(19) United States
(12) Patent Application Publication
(10) Pub. No.: US 2025/0357862 A1
(43) Pub. Date: Nov. 20, 2025

(54) SEMICONDUCTOR INTEGRATED CIRCUIT

(71) Applicant: ROHM CO., LTD., Kyoto (JP)

(72) Inventor: Tadayuki SAKAMOTO, Kyoto (JP)

(21) Appl. No.: 19/203,619

(22) Filed: May 9, 2025

(30) Foreign Application Priority Data
May 17, 2024 (JP) 2024-081173

(51) Int. Cl. H02M 3/158; G01R 19/165; H02M 1/00

(52) U.S. Cl. CPC H02M 3/158; G01R 19/16533; H02M 1/0009

(57) ABSTRACT

A semiconductor integrated circuit includes: a high-side transistor as a PM OS transistor; and an overcurrent detection circuit comparing a current flowing the high-side transistor with a threshold current and including: a voltage-current conversion circuit converting a reference voltage into a reference current; a replica transistor as a PM OS transistor on a path of the reference current and including a source connected to a source of the high-side transistor; and a comparator comparing drain voltages of the high-side and replica transistors, wherein the voltage-current conversion circuit includes: an input terminal receiving the reference voltage; an NM OS transistor as a native transistor; a first resistor connected between a source of the NM OS transistor and a ground; and a voltage divider circuit including second and third resistors connected in series between the input terminal and the ground, and supplying a divided voltage of the reference voltage to a gate of the NM OS transistor.

### CROSS REFERENCE TO RELATED APPLICATION

The present invention claims priority under 35 U.S.C. § 119 to Japanese Patent Application No. 2024-081173, filed on May 17, 2024, the entire contents of which are incorporated herein by reference.

### TECHNICAL FIELD

The present disclosure relates to overcurrent detection.

### BACKGROUND

When an overcurrent flows through a transistor that constitutes a semiconductor integrated circuit, reliability of the transistor or other elements connected to the transistor decreases. For that reason, the semiconductor integrated circuit is provided with an overcurrent protection circuit.

### BRIEF DESCRIPTION OF DRAWINGS

The accompanying drawings, which are incorporated in and constitute a part of the specification, illustrate embodiments of the present disclosure.

FIG. 1 is a circuit diagram of a semiconductor integrated circuit according to an embodiment.

FIG. 2 is a circuit diagram of a semiconductor integrated circuit including an overcurrent detection circuit according to a comparative technique.

FIG. 3 is a circuit diagram of a DC/DC converter including a controller IC according to an embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Summary of Embodiments

A summary of some exemplary embodiments of the present disclosure is described. This summary is intended to provide a simplified description of some concepts of one or more embodiments in order to provide a basic understanding of the embodiments as a prelude to the following detailed description and is not intended to limit the breadth of the disclosure. For the sake of convenience, “one embodiment” may be used to refer to one embodiment (example or modification) or multiple embodiments (examples or modifications) disclosed in this specification.

This summary is not an exhaustive overview of all conceivable embodiments and is not intended to identify key elements of all embodiments or to delineate the scope of some or all aspects. The sole purpose thereof is to present some concepts of one or more embodiments in a simplified form as a prelude to the more detailed description presented later.

A semiconductor integrated circuit according to one embodiment includes a high-side transistor which is a PM OS transistor, and an overcurrent detection circuit configured to compare a current flowing through the high-side transistor with a threshold current. The overcurrent detection circuit includes a voltage-current conversion circuit configured to convert a reference voltage into a reference current, a replica transistor which is a PM OS transistor provided on a path of the reference current output by the voltage-current conversion circuit and including a source connected to a source of the high-side transistor, and a comparator configured to compare a drain voltage of the high-side transistor with a drain voltage of the replica transistor. The voltage-current conversion circuit includes an input terminal configured to receive the reference voltage, an NM OS transistor which is a native transistor, a first resistor connected between a source of the NM OS transistor and a ground, and a voltage divider circuit configured to include a second resistor and a third resistor connected in series between the input terminal and the ground, and supply a voltage, obtained by dividing the reference voltage, to a gate of the NM OS transistor.

With this configuration, it is possible to adjust temperature characteristics of the reference current by adjusting a voltage division ratio of the voltage divider circuit, and to cancel a difference in temperature characteristics between the high-side transistor and the replica transistor. This may reduce temperature dependency of the threshold current of the overcurrent detection circuit. In addition, by using the native transistor as the NM OS transistor, it is possible to reduce fluctuation of the threshold current caused by process variation.

In one embodiment, the replica transistor may include a plurality of PM OS transistors stacked vertically. This makes it possible to reduce a size parameter (W/L) of the replica transistor, thereby reducing an amount of the reference current.

In one embodiment, the overcurrent detection circuit may further include a first switch connected between a drain of the high-side transistor and the source of the high-side transistor.

In one embodiment, the voltage divider circuit may further include a second switch connected in series with the second resistor and the third resistor.

In one embodiment, the voltage-current conversion circuit (V/I conversion circuit) may further include a third switch connected in series with the replica transistor.

In one embodiment, the high-side transistor may be a switching element of a DC/DC converter, and the semiconductor integrated circuit may be a controller IC of the DC/DC converter.

### Embodiments

Preferred embodiments are described below with reference to the drawings. The same or equivalent components, parts, and processes shown in each drawing are designated by the same reference numerals, and duplicate descriptions thereof are omitted as appropriate. Furthermore, the embodiments are not intended to limit the present disclosure but are merely examples. All of the features and combinations thereof described in the embodiments are not necessarily essential to the present disclosure.

In the present disclosure, “a state where a member A is connected to a member B” includes a case where the member A and the member B are physically directly connected or even a case where the member A and the member B are indirectly connected through any other member that does not affect an electrical connection state between the members A and B or does not impair functions and effects achieved by combinations of the members A and B.

Similarly, “a state where a member C is provided between a member A and a member B” includes a case where the member A and the member C or the member B and the member C are indirectly connected through any other member that does not affect an electrical connection state between the members A and C or the members B and C or does not impair functions and effects achieved by combinations of the members A and C or the members B and C, in addition to a case where the member A and the member C or the member B and the member C are directly connected.

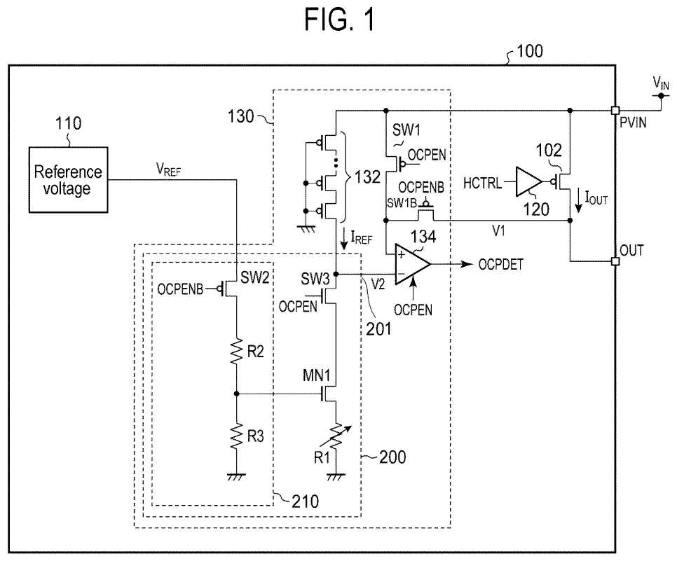

FIG. 1 is a circuit diagram of a semiconductor integrated circuit 100 according to an embodiment. The semiconductor integrated circuit 100 includes a high-side transistor 102, a reference voltage source 110, a high-side driver 120, and an overcurrent detection circuit 130, and is a functional IC integrated on a single semiconductor substrate.

The reference voltage source 110 generates a reference voltage V_{REF}. The reference voltage V_{REF} is supplied to the overcurrent detection circuit 130 and other circuit blocks (not shown).

The high-side transistor 102 is a P-channel MOSFET, a source of which is connected to an input terminal PVIN, and a drain of which is connected to an output terminal OUT. A DC input voltage V_{IN} is supplied to the input terminal PVIN. The output terminal OUT is connected to a load (not shown).

The high-side driver 120 controls on/off operation of the high-side transistor 102 in response to a control signal HCTRL. Specifically, when the control signal HCTRL is at a first level (e.g., low), the high-side driver 120 supplies a low voltage, i.e., a ground voltage of 0 V, to a gate of the high-side transistor 102 to turn the high-side transistor 102 on, and when the control signal HCTRL is at a second level (e.g., high), the high-side driver 120 supplies a high voltage, i.e., an input voltage VIN, to the gate of the high-side transistor 102 to turn the high-side transistor 102 off.

When the high-side transistor 102 is turned on, the overcurrent detection circuit 130 is enabled to compare a current Iₒᵤₜ flowing through the high-side transistor 102 with a threshold current I_{OCP} and assert an overcurrent detection signal OCPDET when I_{OUT}>I_{OCP}. In this embodiment, the overcurrent detection signal OCPDET is negative logic, and—is assigned to assert. The enabled/disabled state of the overcurrent detection circuit 130 is controlled according to an enable signal OCPEN generated by a controller (not shown). When the enable signal OCPEN is asserted (high), the overcurrent detection circuit 130 is enabled (turned on), and when the enable signal OCPEN is negated (low), the overcurrent detection circuit 130 is disabled (turned off).

The overcurrent detection circuit 130 includes a V/I conversion circuit 200, a replica transistor 132, a comparator 134, and a first switch SW1.

The V/I conversion circuit 200 converts the reference voltage V_{REF} into a reference current I_{REF} and outputs the reference current I_{REF}. The replica transistor 132 is a replica of the same type as the high-side transistor 102 and is provided on a path of the reference current I_{REF} generated by the V/I conversion circuit 200, i.e., between an output node 201 of the V/I conversion circuit 200 and the input terminal PVIN. A source of the replica transistor 132 is connected to the source of the high-side transistor 102, i.e., the input terminal PVIN.

A ratio of a size parameter (W/L) of the replica transistor 132 to a size parameter (W/L) of the high-side transistor 102 is set to 1:n, where W represents a gate width and L represents a gate length.

A gate of the replica transistor 132 is grounded. As described above, since the ground voltage is supplied to the gate of the high-side transistor 102 in the on state of the high-side transistor 102, gate-source voltages of the high-side transistor 102 and the replica transistor 132 are equal to each other when the high-side transistor 102 is in the on state.

The comparator 134 compares a drain voltage of the high-side transistor 102 with a drain voltage of the replica transistor 132, and asserts (keeps low) the overcurrent detection signal OCPDET when V1<V2 and negates (keeps high) the overcurrent detection signal OCPDET when V1>V2. The comparator 134 is enabled when the enable signal OCPEN is asserted, and stops operating when the enable signal OCPEN is negated. This makes it possible to reduce power consumption.

When n×I_{REF}=Iₒᵤₜ holds true in the replica transistor 132 and the high-side transistor 102, the drain-source voltages thereof become equal to each other. In other words, V1=V2 holds true. When n×I_{REF}>I_{OUT}, V1>V2 holds true, so the overcurrent detection signal OCPDET is kept high (negated). When an overcurrent state occurs and n×I_{REF}<I_{OUT}, V1<V2 holds true, so the overcurrent detection signal OCPDET is kept low (asserted). In other words, n×I_{REF} is a threshold current I_{OCP} for overcurrent detection.

The first switch SW1 is connected in parallel with the high-side transistor 102. The first switch SW1 is controlled in conjunction with the enable signal OCPEN of the overcurrent detection circuit 130. When the enable signal OCPEN is asserted (kept high), the first switch SW1 is turned off, and when the enable signal OCPEN is negated (kept low), the first switch SW1 is turned on. A switch SW1B is provided between the output terminal OUT and an input terminal of the comparator 134. The switch SW1B is controlled complementarily to the first switch SW1 in response to an inverted enable signal OCPENB.

The V/I conversion circuit 200 includes a voltage divider circuit 210, an NM OS transistor MN1, a first resistor R1, and a third switch SW3.

The NM OS transistor MN1 is a native transistor (native device). The native transistor is intermediate between an enhancement mode and a depletion mode and has a threshold voltage close to zero. The native transistor is a transistor formed without doping for adjusting the threshold voltage in a channel region and is formed on a silicon substrate that is p-type-doped from the beginning without additional doping. A first resistor R1 is connected between a source of the NM OS transistor MN1 and the ground.

The voltage divider circuit 210 includes a second resistor R2 and a third resistor R3 connected in series between an input terminal IN and the ground. The voltage divider circuit 210 supplies a voltage Vg obtained by dividing the reference voltage V_{REF} to a gate of the NM OS transistor MN1. The voltage divider circuit 210 further includes a second switch SW2. The second switch SW2 is controlled according to the inverted signal OCPENB of the enable signal OCPEN. The second switch SW2 is turned on when the inverted enable signal OCPENB is asserted (kept low) and is turned off when the inverted enable signal OCPENB is negated (kept high). This makes it possible to cut off the current path and reduce power consumption when the overcurrent detection circuit 130 is in the disabled state.

The third switch SW3 is provided in series with the NM OS transistor MN1 and is switched on and off in conjunction with the enable signal OCPEN. When the overcurrent detection circuit 130 is in the disabled state, the third switch SW3 is turned off, the current path of the reference current I_{REF} is cut off, and the power consumption is reduced.

The above is a configuration of the V/I conversion circuit 200. Next, an operation of the V/I conversion circuit 200 is described.

The gate voltage Vg of the NM OS transistor MN1 is represented by the following formula (1).

$$Vg = {V}_{REF} \times R 3 / ( R 2 + R 3 ) \qquad ( 1 )$$

As described below, in this embodiment, a voltage division ratio R3/(R2+R3) of the voltage divider circuit 210 is used as a parameter that defines temperature characteristics of the V/I conversion circuit 200.

A source voltage Vs of the NM OS transistor MN1 is represented by the following formula (2).

$$Vs = Vg - Vgs = VREF \times R 3 / ( R 2 + R 3 ) - Vgs \qquad ( 2 )$$

Vgs is a gate-source voltage of the NM OS transistor MN1.

The current I_{REF} flowing through the first resistor R1 and the NM OS transistor MN1 is represented by the following formula (3).

$${I}_{REF} = Vs / R 1 = ( VREF \times R 3 / ( R 2 + R 3 ) - Vgs ) / R 1 \qquad ( 3 )$$

For accurate overcurrent detection, the high-side transistor 102 and the replica transistor 132 need to have matching temperature characteristics. However, in order to reduce power consumption, it is necessary to increase an on-resistance of the replica transistor 132 and reduce a current flowing through the replica transistor 132. For this reason, the replica transistor 132 adopts a structure in which a plurality of PM OS transistors are stacked vertically. When such a configuration is adopted, the high-side transistor 102 and the replica transistor 132 have different temperature characteristics.

In the overcurrent detection circuit 130, the reference current I_{REF} generated by the V/I conversion circuit 200 has temperature characteristics that are capable of cancelling a difference in the temperature characteristics between the high-side transistor 102 and the replica transistor 132.

In the V/I conversion circuit 200, the temperature characteristics of the reference current I_{REF} may be set according to the gate voltage Vg of the NM OS transistor MN1. Since the gate voltage Vg is expressed by formula (1), the temperature characteristics of the reference current I_{REF} are defined by the voltage division ratio determined by resistance values of the resistors R2 and R3.

A relationship between the gate voltage Vg and the temperature characteristics of the reference current I_{REF} is described.

The gate-source voltage Vgs of the NM OS transistor MN1 as the native transistor is assumed to be 0.15 V at the room temperature. A temperature coefficient thereof is also assumed to be k=−1.6 mV/degrees C. Since temperature dependency of the gate voltage Vg in formula (1) may be ignored, the source voltage Vs has the same temperature coefficient as the gate-source voltage Vgs. Therefore, the temperature dependency of the source voltage Vs is represented by −(k/Vs)=1.6 mV/Vs ppm/degrees C. Since Vs=Vg−Vgs, the temperature dependency of the source voltage Vs is represented by α=−k/(Vg−Vgs)=1.6 mV/(Vg-0.15 V) ppm/degrees C. and is expressed as a function of the gate voltage Vg.

The temperature dependency of the reference current I_{REF} generated by the V/I conversion circuit 200 is (1+α)/(1+β)−1, where β is temperature dependency of the first resistor R1, and is, for example, +1,500 ppm/degrees C.

For example, if temperature characteristic of an on-resistance of the high-side transistor 102 is 3,000 ppm and temperature characteristic of an on-resistance of the replica transistor 132 is 3,500 ppm, the temperature dependency Z of the reference current I_{REF} required to cancel them is 500 ppm. In general, α, i.e., the gate voltage Vg, may be determined so as to satisfy Z=(1+α)/(1+β)−1, and the voltage division ratio of the voltage divider circuit 210 may be determined so as to obtain the determined gate voltage Vg.

The overcurrent detection circuit 130 also has an advantage that variation in the threshold current I_{OCP} is small.

In the embodiment, a native transistor is used as the NM OS transistor MN1. The native transistor is not affected by variation in doping of the channel region during the manufacturing process. Therefore, variation in the gate-source voltage Vgs is smaller than that of a non-native transistor. Now, it is assumed that the variation in the gate-source voltage Vgs is +0.025 V and variation in a resistance value is +10%. Since relative variation of the resistors R2 and R3 may be suppressed to a negligible level by pairing, R3/(R2+R3) may be treated as a constant, and only variation of the resistor R1 needs to be considered.

When process variations are taken into consideration, the reference current I_{REF} varies in a range of 88.8% to 113.7% with respect to I_{REF(TYP)}. Therefore, the variation is small.

Advantages of the overcurrent detection circuit 130 become apparent when compared with a comparative technique. The comparative technique is now described.

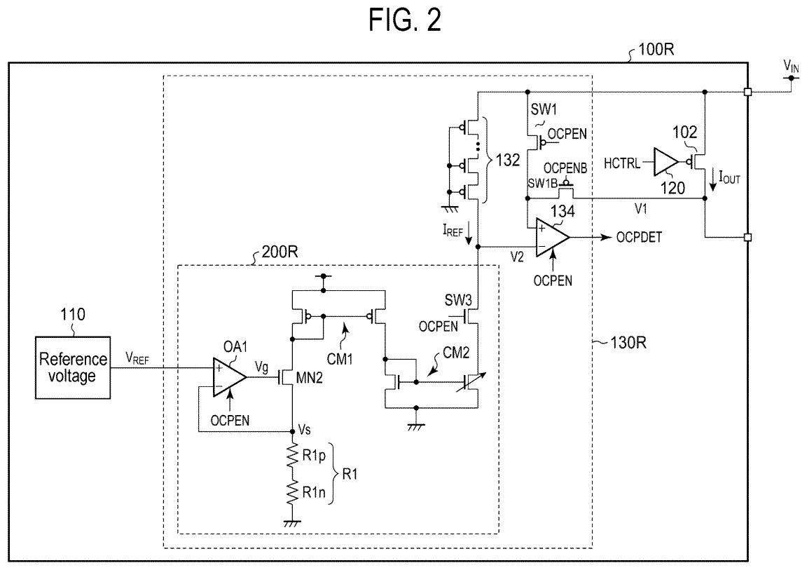

FIG. 2 is a circuit diagram of a semiconductor integrated circuit 100R including an overcurrent detection circuit 130R according to a comparative technique. The overcurrent detection circuit 130R differs in a configuration of a V/I conversion circuit 200R from that shown in FIG. 1. The V/I conversion circuit 200R is of a closed-loop type, in which the voltage divider circuit 210 is omitted and an operational amplifier OA 1 is provided.

Further, the V/I conversion circuit 200R includes an NM OS transistor MN2, which is a conventional non-native transistor, instead of the NM OS transistor MN1, which is a native transistor. Current mirror circuits CM 1 and CM 2 reflect a current flowing through the NM OS transistor MN2 and sink a reference current I_{REF}.

Through negative feedback control using an operational amplifier OA 1, a gate voltage Vg of the NM OS transistor MN2 is adjusted so that an error between a source voltage Vs and a reference voltage V_{REF} becomes zero. Therefore, a current flowing through the first resistor R1 is represented by the following formula (4).

$${I}_{R 1} = {V}_{REF} / R 1 \qquad ( 4 )$$

The current I_{R1} is reflected by the current mirror circuits CM 1 and CM 2 and is output as the reference current I_{REF}. When a current mirror ratio of the current mirror circuits CM 1 and CM 2 is assumed to be 1, the reference current I_{REF} is represented by the following formula (5).

$${I}_{REF} = {V}_{REF} / R 1 \qquad ( 5 )$$

A problem with the overcurrent detection circuit 130R shown in FIG. 2 is now described.

In order to cancel the difference in temperature characteristics between the high-side transistor 102 and the replica transistor 132, the comparative technique also introduces temperature dependency into the reference current I_{REF}. In the comparative technique, a first resistor R1 having temperature characteristics is used to impart the temperature dependency to the reference current I_{REF}. For example, if the temperature characteristic of the on-resistance of the high-side transistor 102 is 3,000 ppm and the temperature characteristic of the on-resistance of the replica transistor 132 is 3,500 ppm, the first resistor R1 only needs to have a temperature characteristic of −500 ppm. The first resistor R1 is configured by a series connection of a resistor R1p having a positive temperature characteristic and a resistor R In having a negative temperature characteristic.

In this configuration, if resistance values of the resistors R1p and R1n are affected by process variations, the temperature characteristic of the first resistor R1 deviates from the design, causing variations in an overcurrent detection threshold value I_{OPC}.

In addition, since the closed-loop type V/I conversion circuit 200R is used, a response time of the V/I conversion circuit 200R is long. Therefore, in applications such as high-speed switching of the high-side transistor 102 and the like, the V/I conversion circuit 200R needs to be kept in constant operation, which results in a problem of increased power consumption.

Returning to FIG. 1, advantages of the overcurrent detection circuit 130 are described. As described above, the overcurrent detection circuit 130 may reduce the variation in the overcurrent detection threshold value I_{OCP}. In addition, since the V/I conversion circuit 200 is an open-loop type, it operates at a high speed. Therefore, in applications such as the high-speed switching of the high-side transistor 102 and the like, it is possible to enable/disable the V/I conversion circuit 200 in conjunction with the switching of the high-side transistor 102, and therefore power consumption may be reduced compared to the comparative technique.

Next, a specific example of the semiconductor integrated circuit 100 is described.

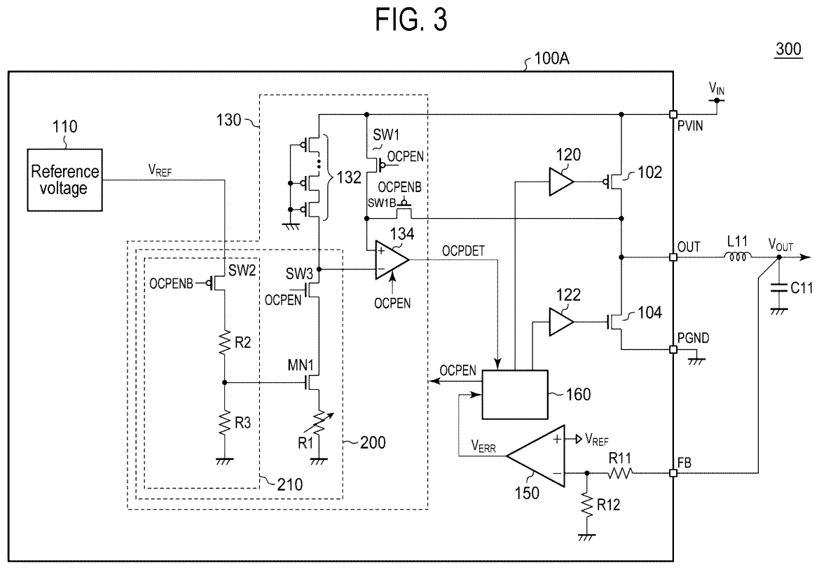

FIG. 3 is a circuit diagram of a DC/DC converter 300 including a controller IC 100A according to an embodiment. The DC/DC converter 300 is a synchronous rectification type step-down converter (Buck converter).

The controller IC 100A has the features of the semiconductor integrated circuit 100 shown in FIG. 1. The controller IC 100A includes a low-side transistor 104, a low-side driver 122, a controller 160, an error amplifier 150, and resistors R11 and R12 in addition to the components of the semiconductor integrated circuit 100 shown in FIG. 1.

An inductor L11 and a capacitor C11 are connected to an output terminal OUT to constitute the DC/DC converter 300 together with the controller IC 100A.

An output voltage V out of the DC/DC converter 300 is fed back to a feedback terminal FB. A voltage of the feedback terminal FB is divided by the resistors R11 and R12. The resistors R11 and R12 may be chip components outside the controller IC 100A. The error amplifier 150 amplifies an error between the feedback voltage V_{FB} and the reference voltage V_{REF}. The controller 160 includes a pulse modulator such as a pulse width modulator or a pulse frequency modulator and generates a pulse signal having a duty cycle according to an output voltage V_{ERR} of the error amplifier 150. The high-side driver 120 and the low-side driver 122 are supplied with control signals HCTRL and LCTRL generated based on the pulse signal.

The overcurrent detection signal OCPDET generated by the overcurrent detection circuit 130 is supplied to the controller 160. The controller 160 performs overcurrent protection in response to the assertion of the overcurrent detection signal OCPDET. For example, the controller 160 may perform pulse-by-pulse overcurrent protection that turns off the high-side transistor 102 each time the overcurrent detection signal OCPDET is asserted. Alternatively, the controller 160 may perform overcurrent protection that stops switching of the high-side transistor 102 and the low-side transistor 104 in response to continuous assertion of the overcurrent detection signal OCPDET.

As described above, the V/I conversion circuit 200 is an open-loop type and is capable of operating at a high speed. Therefore, the controller 160 may generate an enable signal OCPEN for the overcurrent detection circuit 130 in synchronization with the switching of the high-side transistor 102. As a result, while the high-side transistor 102 is turned off, the current flowing through the overcurrent detection circuit 130 is cut off, thereby reducing power consumption.

The application of the technique according to the present disclosure is not limited to the controller IC of the DC/DC converter. For example, the technique according to the present disclosure may also be used in an audio IC having a class D amplifier, a motor driver circuit, and the like.

Further, the high-side transistor is not limited to the switching transistor but may be a simple switch that is constantly turned on.

In the embodiment, the replica transistor 132 is formed as a structure in which multiple PM OS transistors are stacked vertically, but the method for reducing the size parameter (W/L) of the replica transistor 132 is not limited thereto.

The embodiments described using specific terms merely illustrate the principles and applications of the present disclosure. Numerous modifications and changes in arrangement may be made in the embodiments without departing from the spirit of the present disclosure as defined in the claims.

### (Supplementary Note)

The technique disclosed in the present disclosure may be understood in one aspect as follows.

### (Supplementary Note 1)

A semiconductor integrated circuit, including:
a high-side transistor which is a PM OS transistor; and
an overcurrent detection circuit configured to compare a current flowing through the high-side transistor with a threshold current,
wherein the overcurrent detection circuit includes:
   a voltage-current conversion circuit configured to convert a reference voltage into a reference current;
   a replica transistor which is a PM OS transistor provided on a path of the reference current output by the voltage-current conversion circuit and including a source connected to a source of the high-side transistor; and
   a comparator configured to compare a drain voltage of the high-side transistor with a drain voltage of the replica transistor, and
wherein the voltage-current conversion circuit includes:
   an input terminal configured to receive the reference voltage;
   an NM OS transistor which is a native transistor;
   a first resistor connected between a source of the NM OS transistor and a ground; and
   a voltage divider circuit including a second resistor and a third resistor connected in series between the input terminal and the ground, and supplying a voltage, which is obtained by dividing the reference voltage, to a gate of the NM OS transistor.

### (Supplementary Note 2)

The semiconductor integrated circuit of Supplementary Note 1, wherein the replica transistor includes a plurality of PM OS transistors stacked vertically.

### (Supplementary Note 3)

The semiconductor integrated circuit of Supplementary Note 1 or 2, wherein the overcurrent detection circuit further includes a first switch connected between a drain of the high-side transistor and the source of the high-side transistor.

### (Supplementary Note 4)

The semiconductor integrated circuit of any one of Supplementary Notes 1 to 3, wherein the voltage divider circuit further includes a second switch connected in series with the second resistor and the third resistor.

### (Supplementary Note 5)

The semiconductor integrated circuit of any one of Supplementary Notes 1 to 4, wherein the voltage-current conversion circuit further includes a third switch connected in series with the replica transistor.

### (Supplementary Note 6)

The semiconductor integrated circuit of any one of Supplementary Notes 1 to 5, wherein the high-side transistor is a switching element of a DC/DC converter.

While certain embodiments have been described, these embodiments have been presented by way of example only and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor integrated circuit, comprising:
a high-side transistor which is a PM OS transistor; and
an overcurrent detection circuit configured to compare a current flowing through the high-side transistor with a threshold current,
wherein the overcurrent detection circuit includes:
a voltage-current conversion circuit configured to convert a reference voltage into a reference current;
a replica transistor which is a PM OS transistor provided on a path of the reference current output by the voltage-current conversion circuit and including a source connected to a source of the high-side transistor; and
a comparator configured to compare a drain voltage of the high-side transistor with a drain voltage of the replica transistor, and
wherein the voltage-current conversion circuit includes:
an input terminal configured to receive the reference voltage;
an NM OS transistor which is a native transistor;
a first resistor connected between a source of the NM OS transistor and a ground; and
a voltage divider circuit including a second resistor and a third resistor connected in series between the input terminal and the ground, and supplying a voltage, which is obtained by dividing the reference voltage, to a gate of the NM OS transistor.

2. The semiconductor integrated circuit of claim 1, wherein the replica transistor includes a plurality of PM OS transistors stacked vertically.

3. The semiconductor integrated circuit of claim 1, wherein the overcurrent detection circuit further includes a first switch connected between a drain of the high-side transistor and the source of the high-side transistor.

4. The semiconductor integrated circuit of claim 1, wherein the voltage divider circuit further includes a second switch connected in series with the second resistor and the third resistor.

5. The semiconductor integrated circuit of claim 1, wherein the voltage-current conversion circuit further includes a third switch connected in series with the replica transistor.

6. The semiconductor integrated circuit of claim 1, wherein the high-side transistor is a switching element of a DC/DC converter.
